(19) United States
(12) Patent Application Publication
(10) Pub. No.: US 2026/0283047 A1
(43) Pub. Date: Sep. 17, 2026

(54) SEMICONDUCTOR STRUCTURE, FABRICATION METHOD AND PACKAGE STRUCTURE THEREOF

(71) Applicant: Vanguard International Semiconductor Corporation, Hsinchu (TW)

(72) Inventors: Hsiu-Mei Yu, Hsinchu City (TW); Bing-Yu Lin, Hsinchu City (TW); Wei-Chan Chang, Taoyuan City (TW)

(73) Assignee: Vanguard International Semiconductor Corporation, Hsinchu (TW)

(21) Appl. No.: 19/077,008

(22) Filed: Mar. 11, 2025

(51) Int. Cl. H01L 23/498; H01L 21/56; H01L 23/00; H01L 23/14; H01L 23/31; H10D 30/01; H10D 30/47

(52) U.S. Cl. CPC H10W 90/701; H10D 30/015; H10D 30/475; H10W 70/6875; H10W 72/90; H10W 74/016; H10W 74/111; H10W 72/5522; H10W 72/5525; H10W 72/59; H10W 72/952; H10W 90/753

(57) ABSTRACT

A semiconductor structure includes a substrate, a semiconductor layer, a metal carrier, a top metal layer, a redistribution layer and a dielectric material. The substrate has a front surface and a bottom surface. The semiconductor layer is disposed on the front surface of the substrate. The metal carrier is disposed under the bottom surface of the substrate. The top metal layer is disposed on the semiconductor layer. The redistribution layer is electrically connected to the top metal layer. The dielectric material is disposed above the semiconductor layer, and the redistribution layer is embedded in the dielectric material.

### BACKGROUND OF THE INVENTION

### 1. Field of the Invention

The present disclosure relates generally to semiconductor technology, and more particularly to semiconductor structures suitable for high temperature and high operating voltage, and fabrication methods and package structures thereof.

### 2. Description of the Prior Art

With the development of 5G communications, electric vehicle industries, and various electronic products, the demand for high-frequency and high-power semiconductor components is also growing. These high-frequency and high-power semiconductor components, such as high-frequency transistors, high-power field-effect-transistors or high electron mobility transistors (HEMTs), are generally made of compound semiconductors, such as gallium nitride (GaN), silicon carbide (SiC) or other group III-V compound semiconductors. These compound semiconductors have the characteristics of high operating frequency, high breakdown voltage, low on-resistance, etc. The semiconductor devices made of these compound semiconductors are usually used under high-voltage and high-temperature operating conditions. In general, these high-frequency and high-power semiconductor components are bonded and attached to a printed circuit board by conventional packaging methods, such as die bonding, wire bonding, and molding methods.

However, conventional semiconductor structures and packages are usually more suitable for semiconductor devices operating at low voltage and room temperature. For the semiconductor devices operating at high voltage and high temperature, there is still much room for improvement in semiconductor structure, manufacturing and package.

### SUMMARY OF THE INVENTION

In view of this, the present disclosure provides semiconductor structures, fabrication methods and package structures thereof suitable for semiconductor devices operating at high voltage and high temperature. According to the semiconductor structures of the present disclosure, a metal carrier is disposed under the bottom surface of a thinned substrate to enhance heat dissipation efficiency. In addition, during the manufacturing process of these semiconductor structures, the metal carrier supports the thinned substrate or chip, thereby preventing cracks in the semiconductor layer. Meanwhile, the metal carrier facilitates the subsequent formation of a front redistribution layer, thereby improving the yield of semiconductor devices.

According to an embodiment of the present disclosure, a semiconductor structure is provided and includes a substrate, a semiconductor layer, a metal carrier, a top metal layer, a redistribution layer, and a dielectric material. The substrate has a front surface and a bottom surface. The semiconductor layer is disposed on the front surface of the substrate. The metal carrier is disposed under the bottom surface of the substrate. The top metal layer is disposed on the semiconductor layer. The redistribution layer is electrically connected to the top metal layer. The dielectric material is disposed above the semiconductor layer, and the redistribution layer is embedded in the dielectric material.

According to an embodiment of the present disclosure, a package structure is provided and includes a lead frame, a semiconductor structure, a connecting component and an encapsulating material. The semiconductor structure is disposed on the lead frame, where the metal carrier is bonded to the lead frame. The connecting component electrically connects the redistribution layer to the lead frame. The encapsulating material encapsulates the semiconductor structure and the connecting component, and covers the lead frame.

According to an embodiment of the present disclosure, a method of fabricating a semiconductor structure is provided and includes the following steps. An initial substrate is provided and has a front side and a back side. A semiconductor layer is formed on the front side of the initial substrate. A top metal layer is formed on the semiconductor layer. A groove is formed in the semiconductor layer and the initial substrate. After the groove is formed, the back side of the initial substrate is grinded to reduce the thickness of the initial substrate to form a substrate. A metal carrier is provided and bonded to the substrate. A redistribution layer is formed above the semiconductor layer and electrically connected to the top metal layer. A dielectric material is formed to cover the substrate and fill up the groove, where the redistribution layer is embedded in the dielectric material. In addition, the dielectric material, the substrate and the metal carrier are cut along the groove to form a plurality of semiconductor structures separated from each other.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor structure according to an embodiment of the present disclosure.

FIG. 2 is a schematic cross-sectional view of a semiconductor structure according to another embodiment of the present disclosure.

FIG. 3 is a cross-sectional view of a package structure according to an embodiment of the present disclosure.

FIG. 4, FIG. 5, FIG. 6 and FIG. 7 are cross-sectional views of some stages of a method of fabricating a semiconductor structure according to an embodiment of the present disclosure.

FIG. 8 shows cross-sectional views of some intermediate stages of a method of fabricating a semiconductor structure according to another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. For example, if the structure in the figures is turned over, elements described as “below” and/or “beneath” other elements or features would then be oriented “above” and/or “over” the other elements or features. The structures may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

In the present disclosure, a “group III-V compound semiconductor” refers to a compound semiconductor that includes at least one group III element and at least one group V element, where group III element may be boron (B), aluminum (Al), gallium (Ga) or indium (In), and group V element may be nitrogen (N), phosphorous (P), arsenic (As), or antimony (Sb). Furthermore, the group III-V compound semiconductor may be a binary compound semiconductor, a ternary compound semiconductor, or a quaternary compound semiconductor, and includes gallium nitride (GaN), indium phosphide (InP), aluminum arsenide (AlAs), gallium arsenide (GaAs), aluminum gallium nitride (AlGaN), indium aluminum gallium nitride (InAlGaN), indium gallium nitride (InGaN), aluminum nitride (AlN), gallium indium phosphide (GaInP), AlGaAs, InAlAs, InGaAs, or the like, or the combinations thereof, but is not limited thereto.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to semiconductor structures with a metal carrier disposed under the bottom surface of a substrate, as well as their fabrication methods and package structures. The metal carrier significantly improves the heat dissipation efficiency of semiconductor structures, making the semiconductor structures particularly suitable for semiconductor devices operating at high voltages and high temperatures, such as high-frequency and/or high-power semiconductor devices using group III-V compound semiconductors. In addition, during the manufacturing process of the semiconductor structures, the metal carrier supports a thinned substrate, thereby preventing cracks in a semiconductor layer. Furthermore, the metal carrier also benefits the manufacturing of a redistribution layer on the front side of the thinned substrate, thereby avoiding stress from the thicker redistribution layer causing wafer warping, and improving the yield of the semiconductor devices.

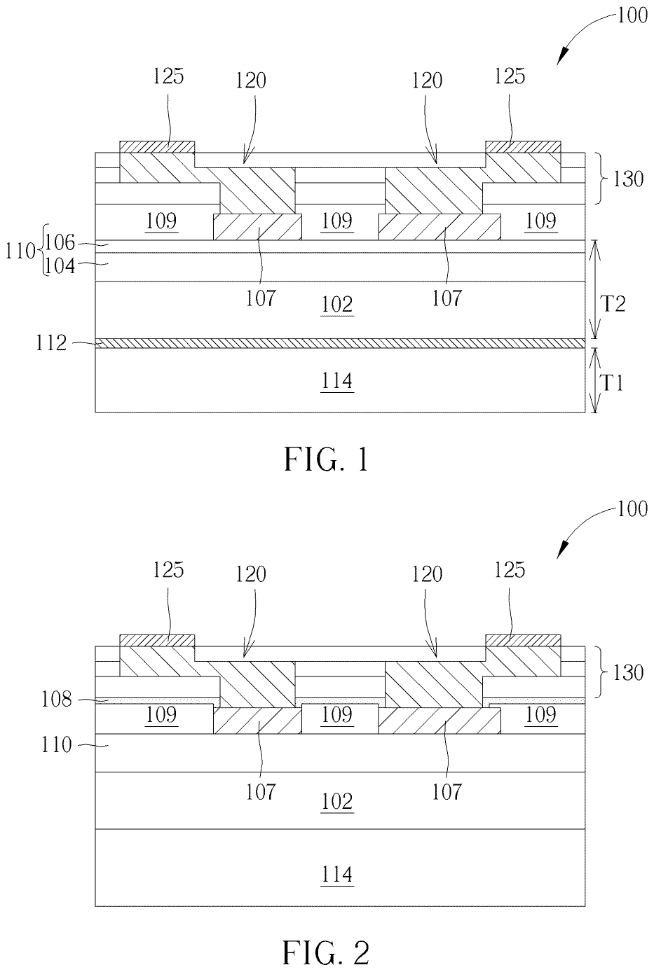

FIG. 1 is a schematic cross-sectional view of a semiconductor structure 100 according to an embodiment of the present disclosure. The semiconductor structure 100 includes a substrate 102, a semiconductor layer 110, a top metal layer 107, a passivation layer 109, a redistribution layer (RDL) 120, a dielectric material 130, and a metal carrier 114. The substrate 102 has a front surface and a bottom surface. The semiconductor layer 110 is disposed on the front surface of the substrate 102, and the metal carrier 114 is disposed under the bottom surface of the substrate 102. In addition, the side surface of the metal carrier 114, the side surface of the substrate 102, the side surface of the semiconductor layer 110, the side surface of the passivation layer 109, and the side surface of the dielectric material 130 may all be on the same plane.

In some embodiments, the substrate 102 may be a semiconductor substrate such as a silicon substrate. Alternatively, the substrate 102 may be a composite substrate such as QST (Qromis Substrate Technology) substrate. The composite substrate includes a composite material layer wrapping a core layer. The core layer is composed of, for example, silicon carbide (SiC), aluminum nitride (AlN), aluminum oxide (Al₂O₃) (also referred to as a sapphire substrate), or a ceramic substrate made of a combination thereof. The composite material layer includes alternately stacked insulating layers and semiconductor bonding layers. The insulating layers are composed of, for example, silicon oxide, silicon nitride, silicon oxynitride, other suitable insulating materials or a combination thereof. The semiconductor bonding layers are composed of, for example, silicon or polysilicon. The compositions of the composite substrate are not limited to the aforementioned materials. Compared to a single-crystal silicon substrate, a QST substrate possesses higher mechanical strength, thereby preventing cracking and/or bending. Furthermore, the QST substrate also offers better heat dissipation. For example, the thermal conductivity (k value) of a silicon substrate is about 1.1 watts per meter·absolute temperature (W/m·K), while the thermal conductivity (k value) of a QST substrate is about 220 W/m·K. A higher thermal conductivity (k value) indicates better thermal conductivity to achieve better heat dissipation. Therefore, the QST substrate is suitable for use as the substrate 102.

According to some embodiments of the present disclosure, the use of a QST substrate provides excellent heat dissipation. For example, the thermal conductivity of the QST substrate is more than 100 times that of a silicon substrate, thereby significantly improving the heat dissipation of the semiconductor structures. Moreover, in the embodiments of the present disclosure, the metal carrier 114 further enhances the heat dissipation of the semiconductor structures. In some embodiments, the metal carrier 114 is, for example, a copper plate, a steel plate, or a stainless steel plate. In addition, the thickness T1 of the metal carrier 114 may be 0.5 to 3 times the total thickness T2 of the substrate 102 and the semiconductor layer 110. For example, the thickness T1 of the metal carrier 114 may be about 400μm to less than 300 μm (e.g., about 250 μm), and the total thickness T2 of the substrate 102 and the semiconductor layer 110 may be about 250 μm to less than 100 μm (e.g., about 80 μm), but is not limited thereto. The thickness of the substrate 102 may be adjusted according to product requirements. The total thickness T2 of the substrate 102 and the semiconductor layer 110 will also change accordingly.

In one embodiment, the semiconductor structure 100 may optionally include a back metal layer 112 disposed between the substrate 102 and the metal carrier 114. The back metal layer 112 facilitates bonding of the metal carrier 114 to the bottom surface of the substrate 102. The back metal layer 112 may be a single-layered structure or a multi-layered structure. The single-layered structure may be composed of, for example, gold (Au), silver (Ag), copper (Cu), or pre-solder. The multi-layered structure may be selected from the group consisting of Ni/Pd/Au, Ti/Ni/Ag, Ti/NiV/Ag, Cu/Ni/Au, Ti/Ni/Au, Ti/Cu, Ti/Au, Ni/Au, Au/As and Al/Ni/Ag.

In some embodiments, the composition of the semiconductor layer 110 may include silicon, polysilicon or group III-V compound semiconductors. The semiconductor layer 110 may be a single semiconductor layer or a semiconductor stack. The single semiconductor layer may be a silicon layer, a polysilicon layer or a group III-V compound semiconductor layer. The semiconductor stack includes stacked semiconductor sub-layers, such as multiple group III-V compound semiconductor sub-layers. Each sub-layer may be composed of, for example, gallium nitride (GaN), indium phosphide (InP), aluminum arsenide (AlAs), aluminum nitride (AlN), gallium arsenide (GaAs), aluminum gallium nitride (AlGaN), indium aluminum gallium nitride (InAlGaN), indium gallium nitride (InGaN), indium gallium phosphide (InGaP), aluminum gallium arsenide (AlGaAs), aluminum indium arsenide (InAlAs) or indium gallium arsenide (InGaAs), but is not limited thereto. In one embodiment, as shown in FIG. 1, the semiconductor layer 110 may include at least a semiconductor channel layer 104 and a semiconductor barrier layer 106, stacked from bottom to top. The semiconductor channel layer 104 may be composed of gallium nitride (GaN), and the semiconductor barrier layer 106 may be composed of aluminum gallium nitride (AlGaN). The semiconductor layer 110 may be used to fabricate a high electron mobility transistor (HEMT) or other high-power transistors.

The top metal layer (TM) 107, such as an aluminum copper (AlCu) layer, is disposed on the semiconductor layer 110. The passivation layer 109 is also disposed on the semiconductor layer 110 and has an opening to expose the top metal layer 107. The composition of the passivation layer 109 may be, for example, silicon oxide, silicon nitride, silicon oxynitride, or a combination thereof. The dielectric material 130 is disposed on the passivation layer 109. According to some embodiments of the present disclosure, the dielectric material 130 is composed of a molding compound, which may be composed of a resin (e.g., epoxy resin, phenolic resin, or unsaturated polyester resin), a hardener, a filler, and other additives. Compared with other insulating materials (e.g., polyimide) or inorganic dielectric materials (e.g., silicon oxide, silicon nitride, and silicon oxynitride), using a molding compound to form the dielectric material 130 provides better heat dissipation efficiency.

The redistribution layer (RDL) 120 includes multiple wire layers and multiple conductive pillars or vias, which are embedded in the dielectric material 130. The redistribution layer 120 is electrically connected to the top metal layer 107, so that transistors fabricated in the semiconductor layer 110 are electrically connected to an external circuit through the top metal layer 107 and the redistribution layer 120. The top surface of the redistribution layer 120 and the top surface of the dielectric material 130 may be on the same plane. In addition, multiple bonding pads 125 may be disposed on the top surface of the redistribution layer 120 for wire bonding or other bonding types. In some embodiments, the composition of the redistribution layer 120 includes copper (Cu) or aluminum (Al). The bonding pad 125 may be a single-layered structure or a multi-layered structure. For example, the single-layered structure of the bonding pad 125 may include gold (Au) or silver (Ag). The multi-layered structure of the bonding pad 125 may be selected from the group consisting of Ni/Au, Ti/Ni/Au, Ti/Cu, Ti/Au, Ni/Pd/Au, Au/As, Ni/Ag and a combination thereof.

FIG. 2 is a schematic cross-sectional view of a semiconductor structure 100 according to another embodiment of the present disclosure. In this embodiment, the semiconductor layer 110 may be a silicon layer, a polysilicon layer, or a combination thereof. Silicon-based transistors, such as trench metal-oxide-semiconductor (TMOS) transistors, laterally diffused metal-oxide-semiconductor (LDMOS) transistors, bipolar junction transistors (BJT), complementary metal-oxide-semiconductor (CMOS) transistors, double-diffused MOS (DMOS) transistors, or a combination thereof, may be fabricated in the semiconductor layer 110. Furthermore, the semiconductor structure 100 may optionally include a patterned insulating layer 108 disposed between the passivation layer 109 and the dielectric material 130. The patterned insulating layer 108 may be composed of polyimide. The patterned insulating layer 108, having a fine pattern, may be formed by exposure and development processes, thereby further controlling the pitch of the exposed portions of the top metal layer 107. Moreover, in this embodiment, there may be no back metal layer disposed between the substrate 102 and the metal carrier 114. The metal carrier 114 may be bonded to the bottom surface of the substrate 102 using silver paste or solder. The details of other features of the semiconductor structure 100 in FIG. 2 may refer to the aforementioned description of the semiconductor structure 100 in FIG. 1, which will not be repeated here.

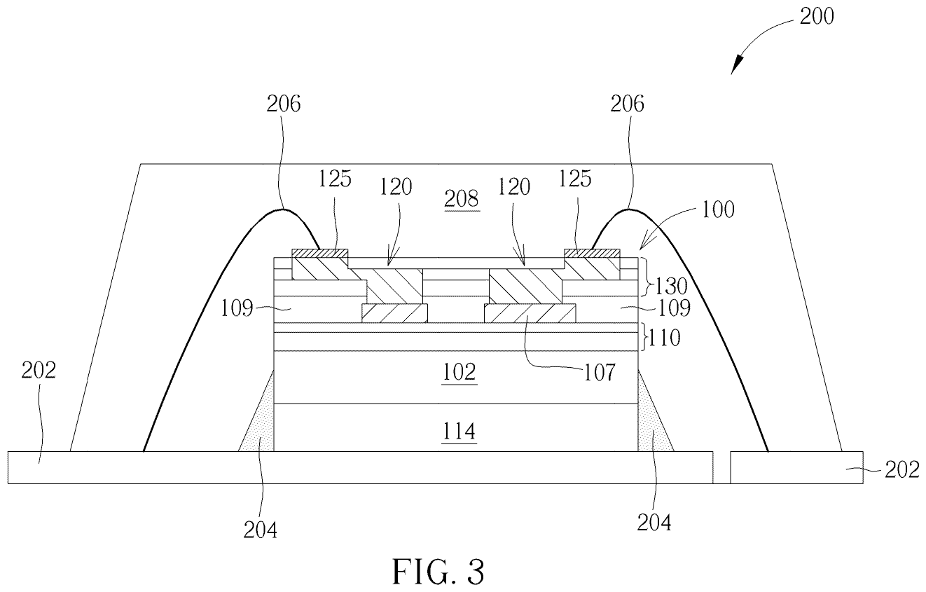

FIG. 3 is a schematic cross-sectional view of a package structure 200 according to an embodiment of the present disclosure. The package structure 200 includes a lead frame 202, a semiconductor structure 100, a bonding material 204, a connecting component 206, and an encapsulating material 208. The semiconductor structure 100 is disposed on the lead frame 202, where the metal carrier 114 may be bonded to the lead frame 202 using silver glue or solder (not shown). Furthermore, the semiconductor structure 100 is bonded to the lead frame 202 using the bonding material 204, such as silver paste or solder. The bonding material 204 is in direct contact with both the side surface of the substrate 102 and the side surface of the metal carrier 114. The bonding pads 125 are disposed on the redistribution layer 120, and the connecting component 206 is bonded to the bonding pads 125, thereby electrically connecting the redistribution layer 120 to the lead frame 202. In some embodiments, the connecting component 206 may be metal wires or metal strips. For example, the metal wires may be gold wires, copper wires, palladium-plated copper (PdCu) wires, or silver wires. The metal strips may be copper sheets, aluminum clips, tin clips, aluminum ribbons, or tin ribbons. The encapsulating material 208 encapsulates the semiconductor structure 100 and the connecting component 206, and covers the lead frame 202. The encapsulating material 208 may be a molding compound, composed of a resin (e.g., epoxy resin, phenolic resin or unsaturated polyester resin), a hardener, a filler, and other additives. In some embodiments, the composition of the encapsulating material 208 may be the same as that of the dielectric material 130 of the semiconductor structure 100.

In the embodiment of FIG. 3, the patterned insulating layer 108 as shown in FIG. 2 may not be disposed between the passivation layer 109 and the dielectric material 130 in the semiconductor structure 100. Furthermore, the back metal layer 112 as shown in FIG. 1 may not be disposed between the substrate 102 and the metal carrier 114. The details of other features of the semiconductor structure 100 in the package structure 200 of FIG. 3 may refer to the aforementioned description of the semiconductor structure 100 in FIG. 1, and will not be repeated here. In other embodiments, the package structure 200 of FIG. 3 is used to package the semiconductor structures 100 of FIG. 1 and FIG. 2.

The package structures 200 of the embodiments of the present disclosure are suitable for various package types, such as a transistor outline (TO) package, a small outline integrated circuit (SOIC) package, a quad flat package (QFP), a dual flat no-lead (DFN) package, a quad flat no-lead (QFN) package, a ball grid array (BGA) package, or other package types.

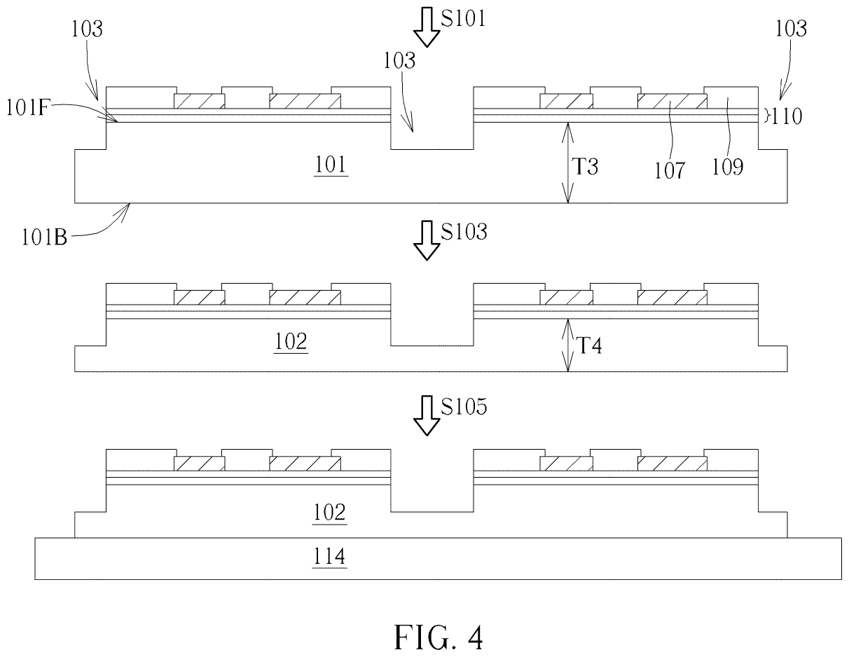

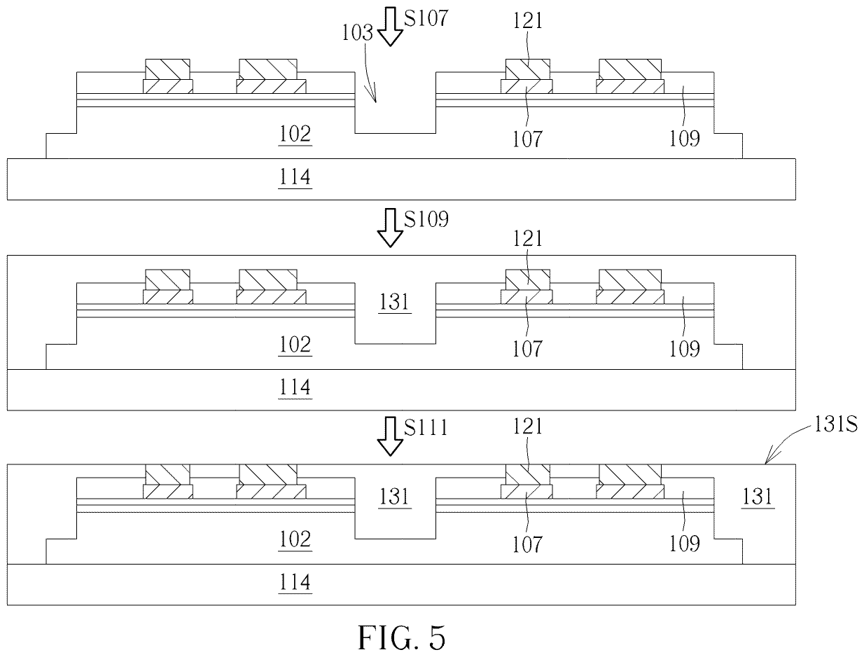

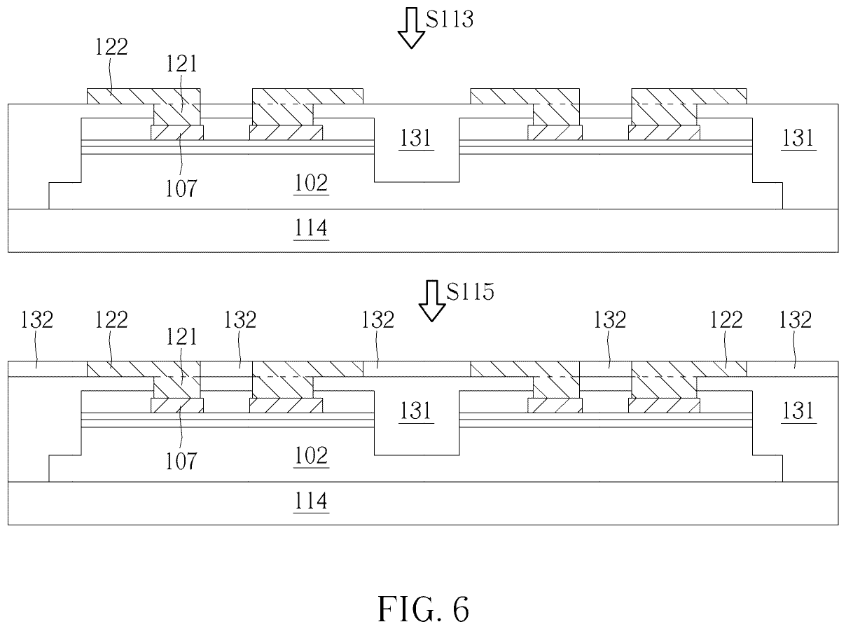

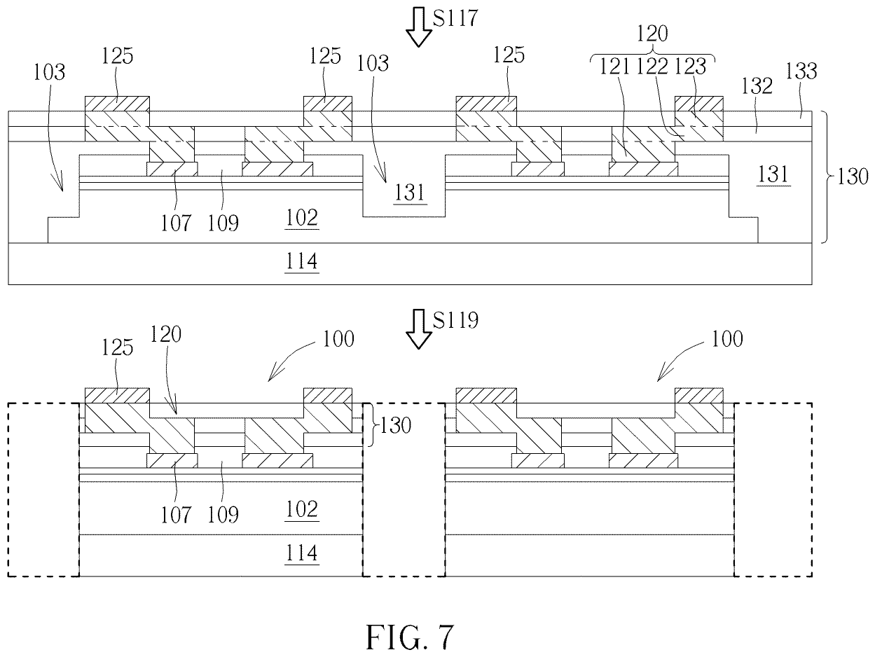

FIG. 4, FIG. 5, FIG. 6 and FIG. 7 are cross-sectional views of some stages of a method of fabricating a semiconductor structure 100 according to an embodiment of the present disclosure. Referring to FIG. 4, in step S101, firstly, an initial substrate 101 is provided and has a front side 101F and a back side 101B. The thickness T3 of the initial substrate 101 is, for example, about 600 μm to about 800 μm. A semiconductor layer 110, such as a silicon layer, a polysilicon layer or a group III-V compound semiconductor stack, is formed on the front side 101F of the initial substrate 101 by an epitaxial growth process. Next, a top metal layer 107 is formed on the semiconductor layer 110 by deposition and patterning processes. A passivation layer 109 is formed on the semiconductor layer 110 by deposition, and then multiple openings are formed in the passivation layer 109 by etching to expose some portions of the top metal layer 107. Afterwards, a laser grooving (LGV) process is applied on the front side 101F of the initial substrate 101 to form multiple grooves 103. These grooves 103 pass through at least the passivation layer 109 and the semiconductor layer 110. The bottom surfaces of the grooves 103 may be located in the initial substrate 101. After the initial substrate 101 is thinned in the subsequent process, these grooves 103 reduce internal stress in the initial substrate 101.

Still referring to FIG. 4, in step S103, a grinding process is applied on the back side 101B of the initial substrate 101 to reduce the thickness T3 of the initial substrate 101, thereby forming a substrate 102. The thickness T4 of the substrate 102 is smaller than the thickness T3 of the initial substrate 101. In some embodiments, the thickness T4 of the substrate 102 is, for example, about 100 μm to about 200 μm. Next, in step S105, a metal carrier 114, such as a copper plate, a steel plate, or a stainless steel plate, is provided. The metal carrier 114 may be bonded to the bottom surface of the substrate 102 using silver glue or solder. In some embodiments, the thickness of the metal carrier 114 is, for example, about 100 μm to about 300 μm. The thickness of the metal carrier 114 may be about 0.5 times to about 3 times the total thickness of the substrate 102 and the semiconductor layer 110.

Referring to FIG. 5, in step S107, metal pillars 121 are formed on the top metal layer 107 by an electroplating process. Next, in step S109, a first molding material 131 is formed by coating and filling processes to fill up the grooves 103 and encapsulate the metal pillars 121. Then, in step S111, a grinding process is applied to the first molding material 131 until the metal pillars 121 are exposed through the surface 131S of the first molding material 131.

Referring to FIG. 6, in step S113, a first wire layer 122 is formed on the first molding material 131 by an electroplating process and is connected to the metal pillars 121. Next, in step S115, a second molding material 132 is formed by coating and filling processes to encapsulate the first wire layer 122. Then, a grinding process is applied to the second molding material 132 to expose the first wire layer 122.

Referring to FIG. 7, in step S117, a second wire layer 123 is formed on the first wire layer 122 by an electroplating process, and is connected to the first wire layer 122. Then, a third molding material 133 is formed by coating and filling processes to encapsulate the second wire layer 123. Next, a grinding process is applied to the third molding material 133 to expose the second wire layer 123. The metal pillars 121, the first wire layer 122, and the second wire layer 123, formed in the aforementioned steps, constitute a redistribution layer 120. The first molding material 131, the second molding material 132, and the third molding material 133, formed in the aforementioned steps, constitute a dielectric material 130. In some embodiments, the first molding material 131, the second molding material 132, and the third molding material 133 may have the same composition, for example, all may be made of epoxy resin. The metal pillars 121, the first wire layer 122 and the second wire layer 123 may be made of the same composition, for example, copper. Additionally, step S113 and step S115 may be repeated to form additional wire layers and molding materials.

In step S117, the redistribution layer 120 is formed above the semiconductor layer 110, embedded in the dielectric material 130, and electrically connected to the top metal layer 107. The dielectric material 130 covers the substrate 102 and the metal carrier 114, filling up the grooves 103. Next, multiple bonding pads 125 are formed on the redistribution layer 120 by an electroplating process, where each of the bonding pads 125 may have a Ni/Au stacked structure. Afterwards, in step S119, the dielectric material 130, the substrate 102, and the metal carrier 114 are cut together using a blade saw or die separation process along the grooves 103, thereby forming multiple separated semiconductor structures 100.

In this embodiment, before forming the metal pillars 121 in step S107, the initial substrate 101 is thinned in step S103 to form the substrate 102, and the metal carrier 114 is bonded to the substrate 102 in step S105.

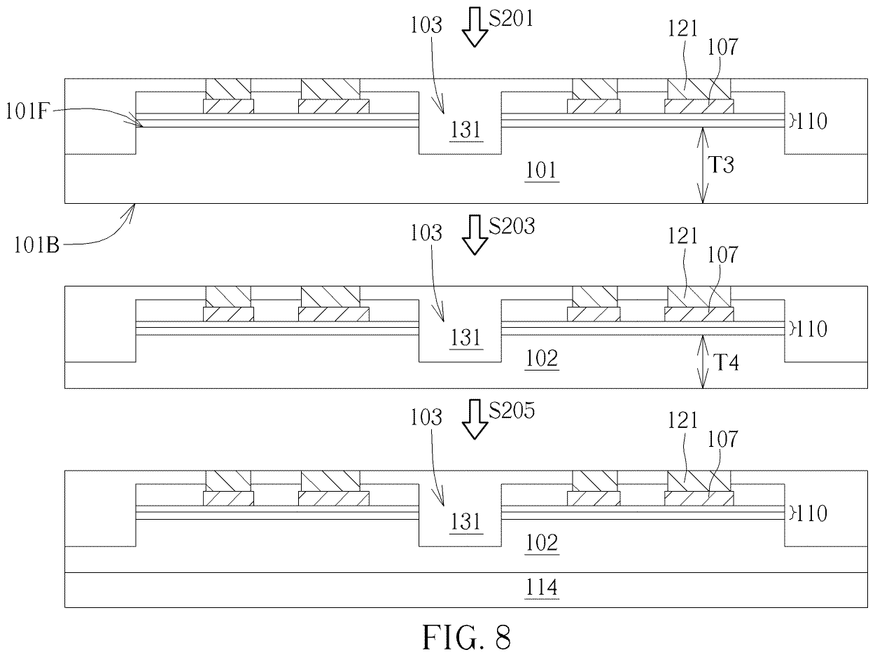

FIG. 8 shows cross-sectional views of some intermediate stages of a method of fabricating a semiconductor structure according to another embodiment of the present disclosure. First, in step S201, an initial substrate 101 is provided, and a semiconductor layer 110 is formed on a front side 101F of the initial substrate 101 by epitaxial growth. A top metal layer 107 is formed on the semiconductor layer 110 by deposition and patterning. A passivation layer 109 is formed on the semiconductor layer 110 by deposition, and then multiple openings are formed in the passivation layer 109 by etching to expose portions of the top metal layer 107. Afterwards, multiple grooves 103 are formed by a laser grooving (LGV) process, passing through the passivation layer 109 and the semiconductor layer 110. The bottom surfaces of the grooves 103 are located in the initial substrate 101. Then, multiple metal pillars 121 are formed on the top metal layer 107 by electroplating. Next, a first molding material 131 is formed to cover the initial substrate 101, fill the grooves 103, and encapsulate the metal pillars 121 by coating and filling. Then, a grinding process is applied to the first molding material 131 until the metal pillars 121 are exposed.

Still referring to FIG. 8, in step S203, a grinding process is applied to the back side 101B of the initial substrate 101 to reduce the thickness T3 of the initial substrate 101, thereby forming a substrate 102. The thickness T4 of the substrate 102 is smaller than the thickness T3 of the initial substrate 101. In some embodiments, the thickness T4 of the substrate 102 is, for example, about 100 μm to about 200 μm. Next, in step S205, a metal carrier 114, such as a copper plate, a steel plate, or a stainless steel plate with surface treatment, is provided. The metal carrier 114 may be bonded to the bottom surface of the substrate 102 using silver glue or solder. Afterward, multiple separated semiconductor structures 100 are formed by following the aforementioned step S113 and step S115 of FIG. 6, and the aforementioned step S117 and step S119 of FIG. 7.

In this embodiment, after forming the metal pillars 121 and grinding the first molding material 131 in step S201, the initial substrate 101 is thinned to form the substrate 102 in step S203, and the metal carrier 114 is bonded to the substrate 102 in step S205.

According to some embodiments of the present disclosure, during the manufacturing process of the semiconductor structures, the metal carrier supports the thinned substrate, thereby preventing cracks in the semiconductor layer. The metal carrier also benefits the manufacturing of the redistribution layer on the front side of the thinned substrate, thereby avoiding stress from the thicker redistribution layer causing substrate warping and improving the yield of the semiconductor devices. In addition, the metal carrier significantly improves the heat dissipation efficiency of the semiconductor structures. Therefore, the semiconductor structures of the present disclosure are particularly suitable for semiconductor devices operating at high voltages and high temperatures, such as high-frequency and/or high-power semiconductor devices using group III-V compound semiconductors.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate, having a front surface and a bottom surface;
a semiconductor layer, disposed on the front surface of the substrate;
a metal carrier, disposed under the bottom surface of the substrate;
a top metal layer, disposed on the semiconductor layer;
a redistribution layer, electrically connected to the top metal layer; and
a dielectric material, disposed above the semiconductor layer, wherein the redistribution layer is embedded in the dielectric material.

2. The semiconductor structure of claim 1, wherein a thickness of the metal carrier is 0.5 to 3 times a total thickness of the substrate and the semiconductor layer, and the metal carrier comprises a copper plate, a steel plate, or a stainless steel plate.

3. The semiconductor structure of claim 1, further comprising a passivation layer, disposed between the semiconductor layer and the dielectric material, wherein the passivation layer has an opening to expose the top metal layer.

4. The semiconductor structure of claim 3, wherein a side surface of the metal carrier, a side surface of the substrate, a side surface of the semiconductor layer, a side surface of the passivation layer, and a side surface of the dielectric material are all on the same plane.

5. The semiconductor structure of claim 3, further comprising a patterned insulating layer, disposed between the passivation layer and the dielectric material, wherein a composition of the patterned insulating layer comprises polyimide, and the dielectric material comprises a molding compound.

6. The semiconductor structure of claim 1, wherein the substrate comprises a semiconductor substrate or a composite substrate, and the composite substrate comprises a core layer and a composite material layer wrapping around the core layer.

7. The semiconductor structure of claim 6, wherein a composition of the semiconductor substrate comprises silicon, a composition of the core layer comprises silicon carbide (SiC), aluminum nitride (AlN), or aluminum oxide (Al₂O₃), and a composition of the composite material layer comprises an insulating layer and a semiconductor bonding layer.

8. The semiconductor structure of claim 1, further comprising a high electron mobility transistor or a silicon-based transistor disposed in the semiconductor layer, wherein a composition of the semiconductor layer comprises a group III-V compound semiconductor, silicon, or polysilicon.

9. The semiconductor structure of claim 1, wherein a top surface of the redistribution layer and a top surface of the dielectric material are on the same plane, and a composition of the redistribution layer comprises copper or aluminum.

10. The semiconductor structure of claim 1, further comprising a back metal layer, disposed between the substrate and the metal carrier, wherein the back metal layer comprises a single-layered structure or a multi-layered structure, a composition of the single-layered structure comprises Au, Ag, Cu, or pre-solder, and a composition of the multi-layered structure is selected from a group consisting of Ni/Pd/Au, Ti/Ni/Ag, Ti/NiV/Ag, Cu/Ni/Au, Ti/Ni/Au, Ti/Cu, Ti/Au, Ni/Au, Au/As, and Al/Ni/Ag.

11. A package structure, comprising:
a lead frame;
the semiconductor structure of claim 1, disposed on the lead frame, wherein the metal carrier is bonded to the lead frame;
a connecting component, electrically connecting the redistribution layer to the lead frame; and
an encapsulating material, encapsulating the semiconductor structure and the connecting component, and covering the lead frame.

12. The package structure of claim 11, wherein a composition of the dielectric material is the same as a composition of the encapsulating material, and both the dielectric material and the encapsulating material comprise a molding compound.

13. The package structure of claim 11, further comprising:
a bonding pad, disposed on the redistribution layer, wherein the connecting component is bonded to the bonding pad; and
a bonding material, adhering the semiconductor structure to the lead frame, wherein the bonding material is in direct contact with both a side surface of the substrate and a side surface of the metal carrier.

14. The package structure of claim 11, wherein the connecting component comprises a metal wire or a metal strip, the metal wire comprises a gold wire, a copper wire, a palladium-plated copper (PdCu) wire, or a silver wire, and the metal strip comprises a copper sheet, an aluminum clip, a tin clip, an aluminum ribbon, or a tin ribbon.

15. A method of fabricating a semiconductor structure, comprising:
providing an initial substrate having a front side and a back side;
forming a semiconductor layer on the front side of the initial substrate;
forming a top metal layer on the semiconductor layer;
forming a groove in both the semiconductor layer and the initial substrate;
grinding the back side of the initial substrate to reduce a thickness of the initial substrate to form a substrate after the groove is formed;
providing a metal carrier to be bonded to the substrate;
forming a redistribution layer above the semiconductor layer, wherein the redistribution layer is electrically connected to the top metal layer;
forming a dielectric material to cover the substrate and fill up the groove, wherein the redistribution layer is embedded in the dielectric material; and
cutting the dielectric material, the substrate and the metal carrier along the groove to form a plurality of semiconductor structures separated from each other.

16. The method of claim 15, wherein forming the redistribution layer and the dielectric material comprises:
forming a metal pillar on the top metal layer;
forming a first molding material to fill up the groove and encapsulate the metal pillar;
grinding the first molding material to expose the metal pillar;
forming a first wire layer on the first molding material, wherein the first wire layer is connected to the metal pillar;
forming a second molding material to encapsulate the first wire layer;
grinding the second molding material to expose the first wire layer;
forming a second wire layer to connect to the first wire layer;
forming a third molding material to encapsulate the second wire layer; and
grinding the third molding material to expose the second wire layer,
wherein the metal pillar, the first wire layer, and the second wire layer constitute the redistribution layer, and the first molding material, the second molding material, and the third molding material constitute the dielectric material.

17. The method of claim 16, wherein before forming the metal pillar, the thickness of the initial substrate is reduced to form the substrate and the metal carrier is bonded to the substrate.

18. The method of claim 16, wherein after the metal pillar is formed and the first molding material is ground, the thickness of the initial substrate is reduced to form the substrate and the metal carrier is bonded to the substrate.

19. The method of claim 15, further comprising:
forming a passivation layer on the semiconductor layer to have an opening to expose the top metal layer,
wherein the groove is further formed in the passivation layer, and forming the groove comprises a laser grooving process applied on the front side of the initial substrate.

20. The method of claim 15, wherein a thickness of the metal carrier is 0.5 to 3 times a total thickness of the substrate and the semiconductor layer, and the metal carrier comprises a copper plate, a steel plate, or a stainless steel plate.
